(19) United States
(12) Patent Application Publication
(10) Pub. No.: US 2010/0000857 A1
(43) Pub. Date: Jan. 7, 2010

(54) COPPER SPUTTERING TARGET MATERIAL AND SPUTTERING METHOD

(75) Inventors: Tatsuya TONOGI, Tsuchiura (JP); Noriyuki Tatsumi, Kasumigaura (JP); Kouichi Isaka, Ishioka (JP); Katsutoshi Honya, Tsuchiura (JP); Masami Odakura, Tsukuba (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 12/494,959

(22) Filed: Jun. 30, 2009

(30) Foreign Application Priority Data
Jul. 1, 2008 (JP) 2008-172718

(51) Int. Cl. C23C 14/34

(52) U.S. Cl. 204/192.15; 204/298.13

(57) ABSTRACT

A copper sputtering target material includes a sputter surface formed of a copper material including one crystal orientation plane and other crystal orientation planes. By application of accelerated specified inert gas ions, the one crystal orientation plane emits sputter particles with energy greater than energy of sputter particles sputtered out of the other crystal orientation planes. The occupying proportion of the one crystal orientation plane to the sum of the one crystal orientation plane and the other crystal orientation planes is not less than 15%.

The present application is based on Japanese patent application No. 2008-172718 filed on Jul. 1, 2008, the entire contents of which are incorporated herein by reference.

### BACKGROUND OF THE INVENTION

1. Field of the Invention

The present invention relates to a copper sputtering target material and sputtering method. In particular, it relates to a copper sputtering target material and sputtering method capable of reducing tensile stress in a formed copper film.

2. Description of the Related Art

Conventionally, in forming a thin metal film such as wiring in electronic devices including a liquid panel, use is made of sputtering using a sputtering target formed of a specified material. As a conventional sputtering target, a sputtering target formed of a face-centered cubic metal or alloy is known that has a plane orientation degree ratio of not less than 2.20 calculated from ((1 1 1) plane+(2 0 0) plane)/(2 2 0) plane.

The above conventional sputtering target has the (1 1 1) plane and (2 0 0) plane preferentially oriented in sputter surface to increase atomic density in the sputter surface, to thereby allow enhancement in sputter rate.

Refer to JP-A-2000-239835.

However, the above conventional sputtering target fails to reduce residual tensile stress in the material film deposited in a vacuum chamber of a sputter apparatus, and may therefore lead to an increase in the material film thickness deposited in the vacuum chamber and peeling-off of the material film, causing particles. Also, although reducing pressure in the vacuum chamber or altering the kind of gas introduced in the vacuum chamber is effective in reducing tensile stress in the material film, because pressure in the vacuum chamber or the kind of gas introduced in the vacuum chamber depends on properties, quality, etc. of the material film to be formed, there is difficulty reducing pressure in the vacuum chamber or altering the kind of gas introduced in the vacuum chamber for the purpose of reducing residual stress.

### SUMMARY OF THE INVENTION

Accordingly, it is an object of the present invention to provide a copper sputtering target material and sputtering method capable of reducing residual tensile stress in a formed copper film, even though not altering film formation conditions (pressure during film formation, kind of gas used in film formation).

(1) According to one embodiment of the invention, a copper sputtering target material comprises:

a sputter surface formed of a copper material comprising one crystal orientation plane and other crystal orientation planes,

wherein by application of accelerated specified inert gas ions, the one crystal orientation plane emits sputter particles with energy greater than energy of sputter particles sputtered out of the other crystal orientation planes, and

wherein the occupying proportion of the one crystal orientation plane to the sum of the one crystal orientation plane and the other crystal orientation planes is not less than 15%.

In the above embodiment, the following modifications and changes can be made.

(i) The one crystal orientation plane is a (1 1 1) plane, and the other crystal orientation planes comprise (2 0 0), (2 2 0), and (3 1 1) planes.

(ii) The occupying proportion is not less than 25%.

(iii) The copper material comprises an oxygen-free copper or a copper alloy comprising copper and inevitable impurities.

(iv) The oxygen-free copper or the copper alloy contains not more than 5 ppm oxygen.

(2) According to another embodiment of the invention, a sputtering method comprises:

forming a copper film on an object to be formed therewith using a copper sputtering target material comprising a sputter surface formed of a copper material comprising one crystal orientation plane and other crystal orientation planes, wherein by application of accelerated specified inert gas ions, the one crystal orientation plane emits sputter particles with energy greater than energy of sputter particles sputtered out of the other crystal orientation planes, and wherein the occupying proportion of the one crystal orientation plane to the sum of the one crystal orientation plane and the other crystal orientation planes is not less than 15%.

Points of the Invention

According to one embodiment of the invention, the copper sputtering target material is formed to have such a sputter surface that, where the sum of the (1 1 1), (2 0 0), (2 2 0) and (3 1 1) crystal orientation planes of the sputter surface is defined as 100%, the proportion occupied by the (1 1 1) plane, i.e., the (1 1 1) plane-occupying proportion is not less than 15%, preferably not less than 25%. By thus setting the (1 1 1) plane-occupying proportion, the energy of sputter particles sputtered out of the sputter surface increases such that internal stress in a copper film formed is changed from tensile into predominantly compressive. Thus, use of the copper sputtering target material in this embodiment for sputtering allows a decrease of residual tensile stress in the sputter film formed.

### BRIEF DESCRIPTION OF THE DRAWINGS

The preferred embodiments according to the invention will be explained below referring to the drawings, wherein:

FIG. 1 is a partial perspective view showing a copper sputtering target in a preferred embodiment according to the invention; and

FIG. 2 is a schematic view showing a sputter apparatus used in sputtering in the embodiment.

### DETAILED DESCRIPTION OF THE PREFERRED EMBODIMENTS

Forming Copper Sputtering Target

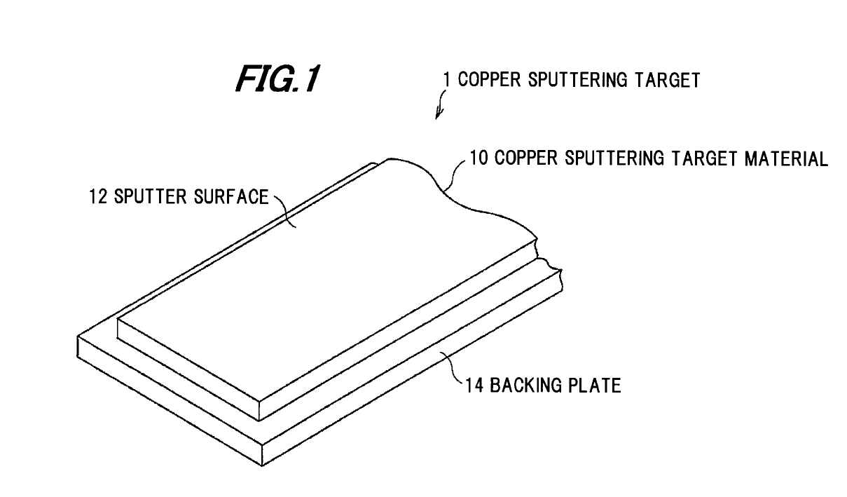

FIG. 1 is a partial perspective view showing a copper sputtering target in the preferred embodiment according to the invention.

A copper sputtering target 1 in this embodiment is formed of a specified copper material whose crystal structure is a face-centered cubic lattice, and comprises a copper sputtering target material 10 having a sputter surface 12 out of which copper sputter particles are sputtered by application of accelerated specified inert gas ions, and a backing plate 14 to which is fixed the copper sputtering target material 10. The copper sputtering target material 10 in this embodiment has a specified thickness and is formed in a substantially rectangular shape viewed from top. As a modification to this embodiment, the copper sputtering target material 10 and backing plate 14 may be formed in a substantially circular shape.

The copper sputtering target material 10 in this embodiment is formed of a copper material comprising an oxygen-free copper or a copper alloy comprising not less than 99.99% purity copper (Cu) and inevitable impurities. The copper alloy may use CuNi as one example. The copper alloy may be formed to contain a metal element such as Al, Ag, or the like. Further, the copper sputtering target material 10 in this embodiment is formed to contain not more than 5 ppm oxygen.

The sputter surface 12 of the copper sputtering target material 10 is formed to comprise plural crystal orientation planes. Namely, the sputter surface 12 is formed of a copper material comprising at least one crystal orientation plane and other crystal orientation planes. Here, the energy of sputter particles sputtered out of the one crystal orientation plane by application of accelerated specified inert gas ions is greater than the energy of sputter particles sputtered out of the other crystal orientation planes. In other words, sputter particles sputtered out of the one crystal orientation plane have the greatest energy of sputter particles including sputter particles sputtered out of the other crystal orientation planes. Further, the sputter surface 12 is formed to have a specified occupying proportion of the one crystal orientation plane to the sum of the one crystal orientation plane and the other crystal orientation planes.

Specifically, the sputter surface 12 comprises (1 1 1) plane as the one crystal orientation plane, and (2 0 0) plane, (2 2 0) plane, and (3 1 1) plane as the other crystal orientation planes. The copper sputtering target material 10 is formed to have the sputter surface 12 so that when the sum of the (1 1 1), (2 0 0), (2 2 0) and (3 1 1) crystal orientation planes of the sputter surface 12 is defined as 100%, the proportion occupied by the (1 1 1) plane, i.e., the (1 1 1) plane-occupying proportion is not less than 15%, preferably not less than 20%, and more preferably not less than 25%.

Here, the (1 1 1) plane-occupying proportion can be calculated from the relative diffraction peak intensity ratio for each crystal orientation measured with X-ray diffraction using “Formula 1” below. Because the diffraction intensity varies according to diffraction surfaces, the correct occupying proportion can be obtained by using corrected values of relative intensity ratios obtained with X-ray diffraction which are corrected by dividing measured values by standard data of ICDD (International Center for Diffraction Data).

$${K}_{s ( 111 )} = \frac{\frac{{I}_{S ( 111 )}}{{I}_{D ( 111 )}}}{[ \frac{{I}_{S ( 111 )}}{{I}_{D ( 111 )}} + \frac{{I}_{S ( 200 )}}{{I}_{D ( 200 )}} + \frac{{I}_{S ( 220 )}}{{I}_{D ( 220 )}} + \frac{{I}_{S ( 311 )}}{{I}_{D ( 311 )}} ]} \times 100 \qquad Formula 1$$

In “Formula 1” above, Ks(111) is the (1 1 1) plane-occupying proportion (%) in a material to be tested, i.e., copper sputtering target material 10, Is(111), Is(200), Is(220), and Is(3 11) are the relative X-ray diffraction peak intensity ratio for each crystal orientation of the material to be tested, and Id(111), Id(200), Id(220), and Id(311) are the relative X-ray diffraction peak intensity ratio for each crystal orientation of standard data.

The higher the energy of sputter particles sputtered out of the sputtering target material by sputtering, the denser the film produced by these sputter particles, so that the internal stress in the film produced varies from tensile to compressive stress. The present inventors have found that as a result of experiment, in the case of copper, the energy of sputter particles sputtered out of the (1 1 1) plane is the highest.

Thus, it has been assumed that increasing the occupying proportion of the (1 1 1) plane to the (1 1 1), (2 0 0), (2 2 0) and (3 1 1) planes of the sputter surface 12 to thereby increase the number of high-energy sputter particles during sputtering allows a decrease of tensile stress in the copper film produced. Accordingly, by examining the (1 1 1) plane-occupying proportion to allow a decrease of tensile stress, it has been found that when the (1 1 1) plane-occupying proportion is not less than 15%, preferably not less than 25%, the internal stress in the copper film formed is reduced. This results in copper sputtering target material 10 formed to have sputter surface 12 so that the (1 1 1) plane-occupying proportion is not less than 15%, as mentioned above. Also, for the purpose of a further decrease of the internal stress in the copper film formed, the copper sputtering target material 10 is formed to have the sputter surface 12 so that the (1 1 1) plane-occupying proportion is not less than 25%.

Sputtering Method

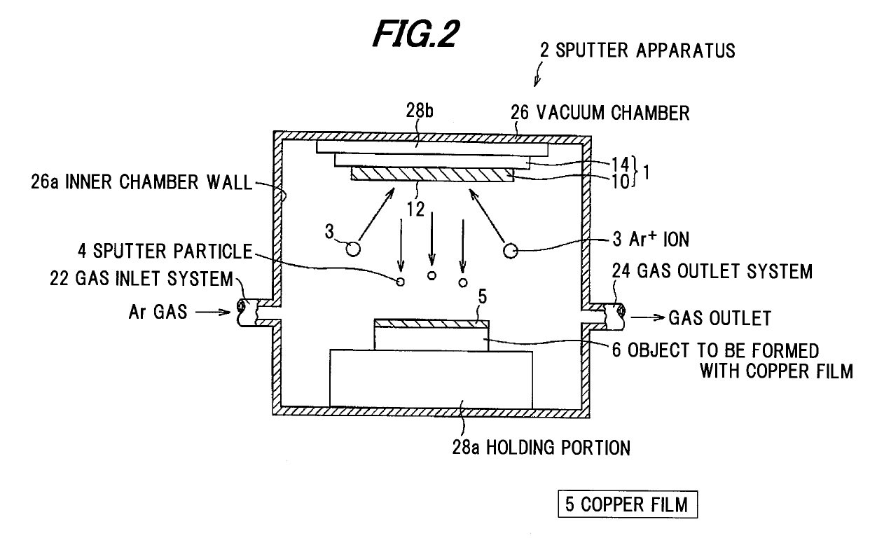

FIG. 2 is a schematic view showing a sputter apparatus used in sputtering in the embodiment according to the invention.

Sputter apparatus 2 comprises a vacuum chamber 26, a holding portion 28a provided at a specified position in the vacuum chamber 26 for holding an object 6 to be formed with a copper film 5 as a metal film, a holding portion 28b provided at a specified position in the vacuum chamber 26 for holding copper sputtering target 1, a gas inlet system 22 for guiding argon gas (Ar gas) as an inert gas, a gas outlet system 24 for venting gas in the vacuum chamber 26, and a power supply (not shown) for applying a specified voltage between the copper sputtering target 1 and the object 6 to be formed with the copper film 5.

The object 6 to be formed with the copper film 5 is a glass substrate formed with a thin film transistor (TFT) used for driving liquid crystal panel pixels, as one example. The sputtering method in this embodiment allows formation of thin film copper wires as 3 kinds of thin film metal wires: TFT gate, source, and drain wires.

The thin film metal wires formed of copper allow a decrease of electrical resistance of the thin film metal wires, compared with thin film metal wires formed of aluminum, for example.

The sputtering method is as follows: First, copper sputtering target 1 and object 6 to be formed with copper film 5 are set in vacuum chamber 26. The vacuum chamber 26 is then set at a specified vacuum pressure, and Ar gas is guided from gas inlet system 22 into the vacuum chamber 26 as an inert gas. A specified voltage is applied to the Ar gas guided into the vacuum chamber 26, to convert the guided Ar gas into plasmas, to thereby produce Ar⁺ ions 3 as inert gas ions. The Ar⁺ions 3 are accelerated by an electric field, to be applied to copper sputtering target material 10. This causes copper forming the copper sputtering target material 10 to be sputtered out as sputter particles 4.

The sputter particles 4 sputtered out of the copper sputtering target material 10 are deposited on the object 6 to be formed with copper film 5, to form copper film 5 thereon. Also, some of the sputter particles 4 sputtered out of the copper sputtering target material 10 (e.g., substantially half of the sputter particles 4 sputtered out of the sputter surface 12) are deposited outside the object 6 to be formed with the copper film 5, e.g., on inner chamber wall 26a to form an adhesive film.

### Advantages of the Embodiment

Since the copper sputtering target material 10 in this embodiment is formed to have the sputter surface 12 so that when the sum of the (1 1 1), (2 0 0), (2 2 0) and (3 1 1) crystal orientation planes of the sputter surface 12 is defined as 100%, the proportion occupied by the (1 1 1) plane, i.e., the (1 1 1) plane-occupying proportion is not less than 15%, preferably not less than 25%, the energy of sputter particles 4 sputtered out of the sputter surface 12 is high as the internal stress in the copper film 5 formed is predominantly compressive. Accordingly, use of the copper sputtering target material in this embodiment for sputtering allows a decrease of residual tensile stress in the sputter film formed.

Also, use of the copper sputtering target material 10 in this embodiment for sputtering allows a decrease of residual tensile stress in the adhesive film adhering to the inner chamber wall 26a of the vacuum chamber 26 of the sputter apparatus 2, and the adhesive film can therefore be inhibited from peeling off when the adhesive film becomes thick. This allows a decrease of residual tensile stress in the adhesive film without altering process pressure and process gas conditions during sputtering, while allowing a decrease of particles produced during sputtering, thus allowing substantial enhancement in TFT yield and productivity, for example.

Also, since the copper sputtering target material 10 in the embodiment according to the invention is formed to contain not more than 5 ppm oxygen, for example, even in the case of using a process gas containing hydrogen gas as reduction atmosphere gas in a liquid crystal panel TFT wiring manufacturing process, the hydrogen gas in the process gas and oxygen in the copper film react to produce H₂O and thereby allow blowholes to be inhibited from being produced in the copper film.

### EXAMPLE 1

Manufacturing Copper Sputtering Target Material 10 in Example 1

First, oxygen-free copper with a purity of 99.99% and an oxygen content of 2 ppm is fabricated by continuous casting as raw material. The oxygen-free copper fabricated by continuous casting is in a 200 mm-thick and 500 mm-wide ingot form. Under a specified atmosphere, this ingot is heated at 800° C., and hot-rolled to a specified thickness of not more than 50 mm.

Subsequently, the hot-rolled material is cold-rolled and heat-treated a specified number of times repeatedly, to fabricate a 18 mm-thick material. In general, it is known that, in case of pure coppers, as the cold reduction ratio increases, the (2 2 0) copper crystal plane-occupying proportion increases. In view of this, in Example 1, the hot-rolled material is then cold-rolled to a reduction ratio of not more than 50%. Then, the cold-rolled material is heat-treated at a temperature lower than 600° C. The reason why the heat treatment is conducted at a temperature lower than 600° C. is because the (3 1 1) copper crystal plane-occupying proportion increases at a temperature higher than 600° C. due to crystal grain cohesion and growth. Thus, the (1 1 1) copper crystal plane-occupying proportion in the rolled surface calculated with “Formula 1” is thereby not less than 15%.

Subsequently, the material with the (1 1 1) plane-occupying proportion being not less than 15% is mechanically cut and removed 1 mm at a time on both its sides, to thereby fabricate a 16 mm-thick copper sputtering target material 10 in Example 1. An X-ray diffractometer analysis of this copper sputtering target material 10 shows that the (1 1 1) plane-occupying proportion is 25.7%. Although Example 1 uses 99.99% oxygen-free copper, the sputtering target material can also be manufactured from a copper alloy, provided that the (1 1 1) copper crystal plane-occupying proportion is not less than 15%.

### EXAMPLE 2

In the same manner as in Example 1, a copper sputtering target material 10 in Example 2 is fabricated. An X-ray diffractometer analysis of the copper sputtering target material 10 in Example 2 shows that the (1 1 1) plane-occupying proportion is 15%.

### EXAMPLE 3

In the same manner as in Example 1, a copper sputtering target material 10 in Example 3 is fabricated. An X-ray diffractometer analysis of the copper sputtering target material 10 in Example 3 shows that the (1 1 1) plane-occupying proportion is 20%.

### COMPARATIVE EXAMPLES

As Comparative Examples, 3 copper sputtering target materials, which show (1 1 1) plane-occupying proportions of less than 15%, are fabricated, adjusting cold working degree and heat treatment temperature. In Comparative Examples, the (1 1 1) plane-occupying proportions of less than 15% is effected by cold rolling the material to a reduction ratio of more than 50%. The X-ray diffractometer measurement of the copper sputtering target materials in the comparative examples shows that the (1 1 1) plane-occupying proportions of the copper sputtering target materials in the comparative examples are 14.6% (Comparative Example 1), 7.6% (Comparative Example 2), and 4.6% (Comparative Example 3). Further, a copper sputtering target material is fabricated in the same process as in Examples of the present invention except that an ingot with an oxygen content of 10 ppm is used as raw material (Comparative Example 4).

Evaluating Copper Sputtering Target Material

Evaluation Method 1: Measuring Residual Stress

Residual stresses in copper foil films formed by sputtering of the copper sputtering target materials in Examples 1 to 3, and Comparative Examples 1 to 4, respectively, are measured. Specifically, for evaluation, the copper sputtering target materials in Examples 1 to 3, and Comparative Examples 1 to 4 are first cut into 5 mm-thick and φ100 mm-diameter discs, respectively. Subsequently, the discs are set in a batch RF power supply sputter apparatus as copper sputtering targets, while a 50 mm-square and 0.7 mm-thick alkali-free glass substrate is set as object 6 to be formed with the copper film.

Using the discs cut out of the copper sputtering target materials in Examples 1 to 3, and Comparative Examples 1 to 4, there are formed 500 nm copper films, respectively, on the alkali-free glass substrate under a specified atmosphere and under a specified pressure condition. Subsequently, residual stress in each of the copper films formed is measured using X-ray diffractometer and Ω-diffractometer method.

Evaluation Method 2: Inspecting Peeling-Off Properties

The peeling-off prevention properties of the copper films deposited in the vacuum chamber of the sputter apparatus are evaluated. Specifically, for evaluation, the copper sputtering target materials in Examples 1 to 3, and Comparative Examples 1 to 4 are first cut into 5 mm-thick and φ100 mm-diameter discs, respectively. In the same manner as in evaluation method 1, this is followed by 0.1 mm-thick copper film formation on a 50 mm-square and 1 mm-thick SUS304 substrate using the batch RF power supply sputter apparatus, and inspection of the presence/absence of copper film peeling-off.

Evaluation Method 3: Evaluating Effect of Oxygen in Copper Film

The effect of oxygen in the copper films formed by sputtering is evaluated. Specifically, for evaluation, the copper sputtering target materials in Examples 1 to 3, and Comparative Examples 1 to 4 are first cut into 5 mm-thick and φ100 mm-diameter discs, respectively. In the same manner as in evaluation method 1, this is followed by 500 nm-thick copper film formation on a 50 mm-square and 0.7 mm-thick alkali-free glass substrate using the batch RF power supply sputter apparatus, and copper film heating in H₂ atmosphere at 300° C. for 30 min and subsequent cooling up to room temperature. Subsequently, the copper films obtained are observed with a scanning electron microscope, to thereby inspect the presence/absence of blowholes.

Table 1 shows the results of the evaluation methods 1 to 3.

TABLE 1

| | (111) plane | | (Evaluation method 1) | (Evaluation method 2) | (Evaluation method 3) |
|---|---|---|---|---|---|
| | occupying proportion | Oxygen content | Residual tensile stress | Presence/absence of | Presence/absence of |
| | (%) | (ppm) | (N/mm²) | film peeling-off | blowholes |
| Example 1 | 25.7 | 2 | 112 | Absence | Absence |
| Example 2 | 15.0 | 2 | 120 | Absence | Absence |
| Example 3 | 20.0 | 2 | 115 | Absence | Absence |
| Comparative | 14.6 | 2 | 123 | Presence | Absence |
| Example 1 | | | | | |
| Comparative | 7.6 | 2 | 125 | Presence | Absence |
| Example 2 | | | | | |
| Comparative | 4.6 | 2 | 139 | Presence | Absence |
| Example 3 | | | | | |
| Comparative | 25.0 | 10 | 114 | Absence | Presence |
| Example 4 | | | | | |

Referring to the evaluation method 1 column in Table 1, it is shown that the residual tensile stresses of the copper films formed of the copper sputtering target materials in Examples 1 to 3 are not more than 120 N/mm², and that the copper film formed of the copper sputtering target material in Example 1 has the lowest residual tensile stress. Also, as seen from the evaluation method 2 column in Table 1, the copper films formed of the copper sputtering target materials in Examples 1 to 3 cause no peeling-off from the SUS304 substrate. Further, as seen from the evaluation method 3 column in Table 1, no blowholes are caused in the copper films formed of the copper sputtering target materials in Examples 1 to 3.

On the other hand, as seen from the evaluation method 1 column in Table 1, the copper films formed of the copper sputtering target materials in Comparative Examples 1 to 3 have large residual tensile stresses, and as seen from the evaluation method 2 column, copper film peeling-off from the SUS304 substrate is observed in the copper films formed of the copper sputtering target materials in Comparative Examples 1 to 3. Also, as seen from the evaluation method 1 column in Table 1, the copper film formed of the copper sputtering target material in Comparative Example 4 has the low residual tensile stress, and as seen from the evaluation method 2 column, no copper film peeling-off from the SUS304 substrate is observed in the copper film formed of the copper sputtering target material in Comparative Example 4, but as seen from the evaluation method 3 column, blowholes are observed that are caused due to the high oxygen content.

From the foregoing, it is shown that the use of the copper sputtering target materials with a (1 1 1) plane-occupying proportion of not less than 15%, desirably not less than 25%, and an oxygen content of not more than 5 ppm, allows a decrease of residual tensile stress in the copper film formed by sputtering.

Although the invention has been described with respect to the above embodiments, the above embodiments are not intended to limit the appended claims. Also, it should be noted that not all the combinations of the features described in the above embodiments are essential to the means for solving the problems of the invention.

What is claimed is:

1. A copper sputtering target material, comprising:
a sputter surface formed of a copper material comprising one crystal orientation plane and other crystal orientation planes,
wherein by application of accelerated specified inert gas ions, the one crystal orientation plane emits sputter particles with energy greater than energy of sputter particles sputtered out of the other crystal orientation planes, and
wherein the occupying proportion of the one crystal orientation plane to the sum of the one crystal orientation plane and the other crystal orientation planes is not less than 15%.

2. The copper sputtering target material according to claim 1, wherein
the one crystal orientation plane is a (1 1 1) plane, and
the other crystal orientation planes comprise (2 0 0), (2 2 0), and (3 1 1) planes.

3. The copper sputtering target material according to claim 1, wherein
the occupying proportion is not less than 25%.

4. The copper sputtering target material according to claim 1, wherein
the copper material comprises an oxygen-free copper or a copper alloy comprising copper and inevitable impurities.

5. The copper sputtering target material according to claim 4, wherein
the oxygen-free copper or the copper alloy contains not more than 5 ppm oxygen.

6. A sputtering method, comprising:
forming a copper film on an object to be formed therewith using a copper sputtering target material comprising a sputter surface formed of a copper material comprising one crystal orientation plane and other crystal orientation planes, wherein by application of accelerated specified inert gas ions, the one crystal orientation plane emits sputter particles with energy greater than energy of sputter particles sputtered out of the other crystal orientation planes, and wherein the occupying proportion of the one crystal orientation plane to the sum of the one crystal orientation plane and the other crystal orientation planes is not less than 15%.
